(19) United States
(12) Patent Application Publication
(10) Pub. No.: US 2026/0313878 A1
(43) Pub. Date: Oct. 8, 2026

(54) SEMICONDUCTOR STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YU-CHIEN CHIU, HSINCHU COUNTY (TW); CHEN-JUN WU, HSINCHU CITY (TW); YA-YUN CHENG, TAICHUNG CITY (TW); WEN-LING LU, TAOYUAN CITY (TW); KATHERINE H. CHIANG, NEW TAIPEI CITY (TW); CHUNG-WEI WU, HSIN-CHU COUNTY (TW); ZHIQIANG WU, HSINCHU COUNTY (TW)

(21) Appl. No.: 19/097,895

(22) Filed: Apr. 2, 2025

(51) Int. Cl. H10B 12/00; H10D 30/63; H10D 62/17; H10D 62/60

(52) U.S. Cl. CPC H10B 12/33; H10B 12/05; H10B 12/09; H10B 12/482; H10B 12/488; H10B 12/50; H10D 30/63; H10D 62/292; H10D 62/314; H10D 62/60

(57) ABSTRACT

A semiconductor structure is provided. The semiconductor structure includes a base layer, a memory element, a logic device, first conductive regions, gate structures and channel regions and second conductive regions. The base layer has a memory area and a logic area. The memory element is disposed in the memory area and the logic device is disposed in the logic area. The first conductive regions are disposed over the base layer in the memory area and the logic area. The gate structures and channel regions are disposed over the first conductive regions in the memory area and the logic area. The channel regions are disposed on and electrically connect to the first conductive regions and are surrounded by the gate structures. The second conductive regions are disposed over the channel regions and the gate structures in the memory area and the logic area.

### BACKGROUND

The semiconductor manufacturing industry has experienced exponential growth over the last few decades. In the course of semiconductor evolution, functional density (i.e., the number of interconnected devices per chip area) has generally increased while geometry size (i.e., the smallest component or line that can be created using a fabrication process) has generally decreased. One advancement has been the development of semiconductor structures, such as transistors, employing metal gates insulated by materials having a high dielectric constant (κ). Such semiconductor structures have improved performance with decreased feature sizes, relative to traditional polysilicon gates insulated by silicon dioxide.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a perspective view of a semiconductor structure, in accordance with some embodiments of the present disclosure.

FIG. 2 illustrates a perspective view of a semiconductor structure, in accordance with some another embodiments of the present disclosure.

FIG. 3 illustrates a cross-sectional side view of a semiconductor structure, in accordance with some embodiments of the present disclosure.

FIG. 4A illustrates a perspective view of a counterpart channel structure of a semiconductor structure, in accordance with some embodiments of the present disclosure.

FIG. 4B illustrates a cross-sectional front view of the counterpart channel structure of the semiconductor structure of FIG. 4A, in accordance with some embodiments of the present disclosure.

FIG. 5A illustrates a perspective view of a counterpart channel structure of a semiconductor structure, in accordance with some another embodiments of the present disclosure.

FIG. 5B illustrates a cross-sectional front view of the counterpart channel structure of the semiconductor structure of FIG. 5A, in accordance with some another embodiments of the present disclosure.

FIGS. 6A to 6D show schematic diagrams showing connections of first and second conductive lines functioned as bit lines and word lines in a logic area, in accordance with some another embodiments of the present disclosure.

FIG. 7 is a perspective view of a semiconductor structure, in accordance with some another embodiments of the present disclosure.

FIG. 8A illustrates a perspective view of counterpart channel structures of a semiconductor structure, in accordance with some another embodiments of the present disclosure.

FIG. 8B illustrates a cross-sectional front view of one of the counterpart channel structures of the semiconductor structure of FIG. 8A, in accordance with some another embodiments of the present disclosure.

FIG. 9 is a flowchart of a method for forming the semiconductor structure in accordance with some embodiments.

FIGS. 10A to 10R illustrate various perspective views of forming the semiconductor structure in accordance with some embodiments as described in FIG. 9.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A trend in the semiconductor manufacturing industry is to integrate different semiconductor components of a composite semiconductor structure into a common semiconductor structure. Such integration advantageously allows lower manufacturing costs, simplified manufacturing procedures, and increased operational speed. A semiconductor structure includes a memory area and a logic area. Generally, within the memory area, bit lines are placed above transistors located in a level so as to electrically connect to memory elements located in an overlying level, while within the logic area, the bit lines require deep bit-line vias formed in the level where the transistors are located so as to electrically connect to logic circuits in the overlying level. Since the structures formed in the memory area are different from those formed in the logic area in the same layer (in some embodiments, in the same level), the memory area and the logic area in such level have to be separately formed, which takes time. Furthermore, a large area is required for the deep bit-line vias, which results in issues of area consumption and lower application density. There is a need to provide a semiconductor structure with high density under a same chip size and a method for manufacturing the semiconductor structure including a memory area and a logic area in an effective way.

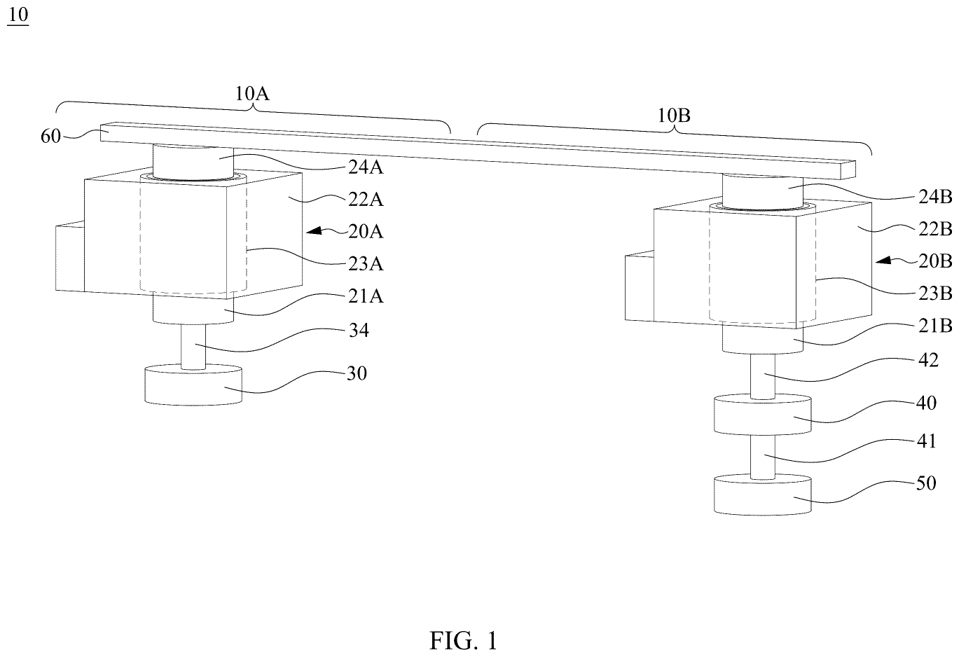

Referring to FIG. 1, the semiconductor structure 10 includes a memory area 10A an a logic area 10B. In some embodiments, the semiconductor structure 10 may include other regions. The memory area 10A comprises at least one transistor 20A including a first conductive region 21A, a gate structure 22A, a channel region 23A and a second conductive region 24A in one level. At the same level, the logic area 10B comprises at least one counterpart transistor 20B. The logic area 10B comprises at least one counterpart transistor 20B including a first conductive region 21B, a gate structure 22B, a channel region 23B and a second conductive region 24B in the same layer (in some embodiments, in the same level). The transistor 20A in the memory area 10A may have a substantially identical structure to the counterpart transistor 20B in the logic area 10B. The transistor 20A and the logic area 10B may share one or more first conductive lines 60, which can be functioned as bit lines (BL), so that the first conductive lines 60 extend from the memory area 10A to the logic area 10B.

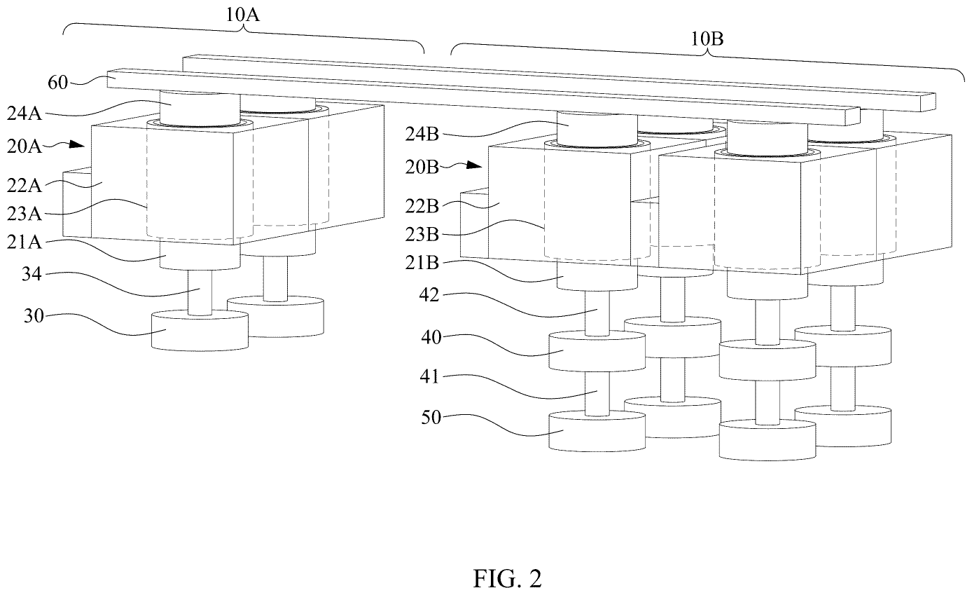

The number of the transistor 20A in the memory area 10A and the number of the counterpart transistor 20B in the logic area 10B can be varied according to required design. For example, as shown in FIG. 1, the semiconductor structure 10 comprises at least one transistor 20A in the memory area 10A and at least one counterpart transistor 20B in the logic a rea 10B, which electrically connect to one first conductive line 60. The number of the transistor 20A in the memory area 10A is identical to the number of the counterpart transistor 20B in the logic area 10B. In some another embodiments as shown in FIG. 2, the number of the transistor 20A in the memory area 10A is different from the number of the counterpart transistor 20B in the logic area 10B. Several first conductive lines 60 can be disposed in the semiconductor structure 10. The semiconductor structure 10 comprises at least one transistor 20A in the memory area 10A and two counterpart transistors 20B in the logic area 10B, which electrically connect to each of first conductive line 60. For one first conductive line 60, the number of the transistor 20A in the memory area 10A may be identical to or different from the number of the counterpart transistor 20B in the logic area 10B. In some embodiments, the number of the transistor 20A in the memory area 10A may be greater than or less than the number of the counterpart transistor 20B in the logic area 10B.

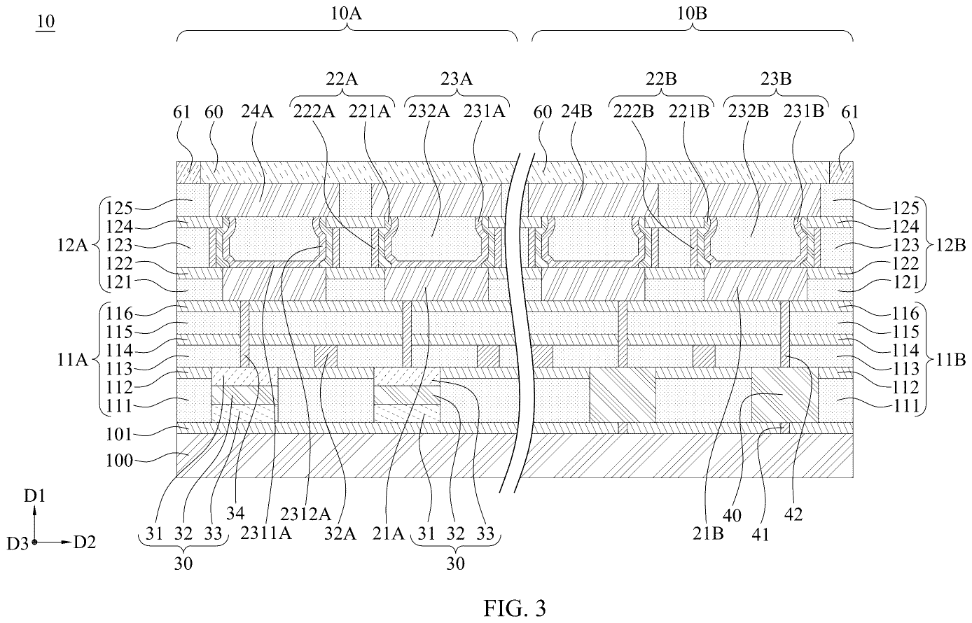

Further referring to FIG. 3, the semiconductor structure 10 may comprise a substrate 100, a first level 11A and 11B, a second level 12A and 12A and the first conductive lines 60, which can be functioned as bit lines. The substrate 100 is fabricated in the front-end-of-line (FEOL) and can be overlaid with a lower insulating layer 101.

In some embodiments, within the memory area 10A, a plurality of dielectric layers (including a first dielectric layer 111, a second dielectric layer 113 and a third dielectric layer 115) and a plurality of insulating layers (including a first insulating layer 112, a second insulating layer 114 and a third insulating layer 116) stack alternately along a first direction D1 are disposed in the first level 11A. In some embodiments, the dielectric layers 111, 113 and 115 include materials different from materials of the insulating layers 112, 114 and 116.

The first dielectric layer 111 can be disposed on a substrate 100 and can be overlaid with the first insulating layer 112. A plurality of memory elements 30 are disposed in the first dielectric layer 111. In some embodiments, the memory element 30 is a capacitor. A top portion of each of the plurality of memory elements 30 is laterally surrounded by the first insulating layer 112. In some embodiments, the plurality of memory elements 30 are exposed from the first insulating layer 112. The first dielectric layer 111 may include a dielectric material such as, but not limited to, oxide, a low-k material, or combinations thereof. For example, the first dielectric layer 111 may include, but not limited to, silicon oxide (SiO₂), hafnium silicate (HfSiO₄), zirconium silicate (ZrSiO₄), or combinations thereof. The first insulating layer 112 may include, but not limited to a metal oxide or an oxidized metal such as such as AlOₓ (such as Al₂O₃), WOₓ, HfOₓ (such as HfO₂), or the like, or combinations thereof. Each of the plurality of memory elements 30 may comprise a capacitor including a bottom electrode 31, a top electrode 33 and a medium structure 32 formed between the bottom electrode 31 and the top electrode 33. In some embodiments, the medium structure 32 may include one or more layers, such as a free layer, a ferroelectric layer, a dielectric layer and/or the like. In some embodiments, the dielectric layer includes a high-k dielectric material. In such embodiments, the dielectric layer includes ZrO, HZo, AZO, and HSO, but the disclosure is not limited thereto.

The second dielectric layer 113 is disposed over the first insulating layer 112 and the plurality of memory elements 30. The second dielectric layer 113 can be overlaid with the second insulating layer 114, and a plurality of second conductive lines 32A is disposed in the second dielectric layer 113. The plurality of second conductive lines 32A are disposed in the second dielectric layer 113 and on the first insulating layer 112 so as to located between the first insulating layer 112 and the second insulating layer 114. The plurality of second conductive lines 32A may be arranged in parallel along a second direction D2, perpendicular to the first direction D1, and may be functioned as word lines (WL). The plurality of second conductive lines 32A may comprise conductive materials. In some embodiments, the second dielectric layer 113 may comprise materials identical or similar to materials of the first dielectric layer 111. The second insulating layer 114 may comprise materials identical or similar to materials of the first insulating layer 112.

The third dielectric layer 115 is disposed over the second insulating layer 114. The third dielectric layer 115 can be overlaid with the third insulating layer 116. In some embodiments, the third dielectric layer 115 may comprise materials identical or similar to materials of the second dielectric layer 113. The third insulating layer 116 may comprise materials identical or similar to materials of the second insulating layer 114.

In some embodiments, within the logic area 10B, the plurality of dielectric layers (including the first dielectric layer 111, the second dielectric layer 113 and the third dielectric layer 115) and the plurality of insulating layers (including the first insulating layer 112, the second insulating layer 114 and the third insulating layer 116) stack alternately along a first direction D1 are also disposed in the first level 11A. The first level 11B comprises a plurality of conductive pads 40 and a plurality of second vias 42. The plurality of conductive pads 40 are disposed in the first dielectric layer 111. Therefore, the memory elements 30 and the plurality of conductive pads 40 are formed in the same layer and also in the same level. The plurality of conductive pads 40 may electrically connect to the logic devices 50 through first vias 41. . The logic devices 50 may be formed by FEOL operations. In some embodiments, the logic devices 50 and the memory element 30 (i.e., the capacitor) are disposed in different levels. For example, the logic devices 50 are disposed in a level underlying or lower than a level where the memory elements 30 are disposed. In some embodiments, the conductive pads 40 and the memory elements 30 are in a same level. In such embodiments, a top surface of the conductive pad 40 may be aligned with memory element 30, but the disclosure is not limited thereto. In other embodiments, the conductive pads 40 and the memory elements 30 may be in different levels.

The plurality of second vias 42 electrically connect the plurality of conductive pads 40 to the counterpart transistor 20B fabricated in the second level 12B. The plurality of first vias 41 comprises conductive materials, such as metals or other conductive materials, including but not limited to tungsten, ruthenium, molybdenum, cobalt, aluminum, nickel, copper, silver, gold, alloys thereof, or the like. In some embodiments, the plurality of first vias 41 may comprise materials identical to the materials for forming the plurality of conductive pads 40. The plurality of second vias 42 comprises conductive materials, such as metals or other conductive materials, including but not limited to tungsten, ruthenium, molybdenum, cobalt, aluminum, nickel, copper, silver, gold, alloys thereof, or the like. In some embodiments, the plurality of second vias 42 may comprise materials identical to the materials for forming the plurality of conductive pads 40. In some embodiments, the plurality of second vias 42 may comprise materials identical to the materials for forming the plurality of first vias 41.

In some embodiments, within the memory area 10A, the second level 12A is formed over the first level 11A. In some embodiments, a plurality of dielectric layers (including a fourth dielectric layer 121, a fifth dielectric layer 123 and a sixth dielectric layer 125) and a plurality of insulating layers (including a fourth insulating layer 122 and a fifth insulating layer 124) stacking alternately along the first direction D1 are disposed in the second level 12B. In some embodiments, the dielectric layers 121, 123 and 125 include materials different from materials of the insulating layers 122, 124 and 126.

The fourth dielectric layer 121 is disposed over the third insulating layer 116 in the first level 11A. The fourth dielectric layer 121 can be overlaid with the fourth insulating layer 122, and a plurality of first conductive regions 21A is disposed in the fourth dielectric layer 121. The plurality of first conductive regions 21A are disposed on the third insulating layer 116 and electrically connect to the memory elements 30 by a plurality of connecting lines 34, each extending from the first conductive region 21A, through the third insulating layer 116, the third dielectric layer 115, the second insulating layer 114 and the second dielectric layer 113, to the memory element 30. In some embodiments, a top portion of each of the plurality of first conductive regions 21A is laterally surrounded by the fourth insulating layer 122. In some embodiments, a top of each of the plurality of first conductive region 21A is exposed from the fourth insulating layer 122. In some embodiments, the first conductive regions 21A may be referred to as source/drain regions. In some embodiments, the first conductive regions 21A can be referred to as source regions. In some embodiments, the first conductive regions 21A comprise tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. The plurality of connecting lines 34 may comprise materials identical or similar to the materials of the first conductive regions 21A. In some embodiments, the fourth dielectric layer 121 may comprise materials identical or similar to materials of the third dielectric layer 115. The fourth insulating layer 122 may comprise materials identical or similar to the materials of the third insulating layer 116.

The fifth dielectric layer 123 is disposed over the fourth insulating layer 122 and the first conductive region 21A. The fifth dielectric layer 123 can be overlaid with the fifth insulating layer 124. In some embodiments, the fifth dielectric layer 123 may comprise materials identical or similar to materials of the fourth dielectric layer 121. The fifth insulating layer 124 may comprise materials identical or similar to the materials of the fourth insulating layer 122. The fifth dielectric layer 123 comprises a plurality of channel regions 23A, each of the plurality of channel regions 23A surrounded by a gate structure 22A. Each of the plurality of channel regions 23A comprises a channel layer 231A and a central isolation structure 232A. The channel layer 231A has a U shape and serves as a bottom and a sidewall of the central isolation structure 232A. In some embodiments, the channel layer 231A has a bottom segment 2311A and sidewalls 2312A. In some embodiments, the bottom segment 2311A of the channel layer 231A contacts the first conductive region 21A. The sidewalls 2312A may be substantially straight linear, curved, or other regular or irregular configuration. The central isolation structure 232A is disposed on the bottom segment 2311A of the channel layer 231A and is sandwiched by the sidewalls 2312A of the channel layer 231A. The central isolation structure 232A has a configuration corresponding to the configuration of the sidewalls 2312A of the channel layer 231A. In some embodiments as shown in FIG. 3, the central isolation structure 232A may have an oblate cross-section with narrower top and bottom than a middle portion.

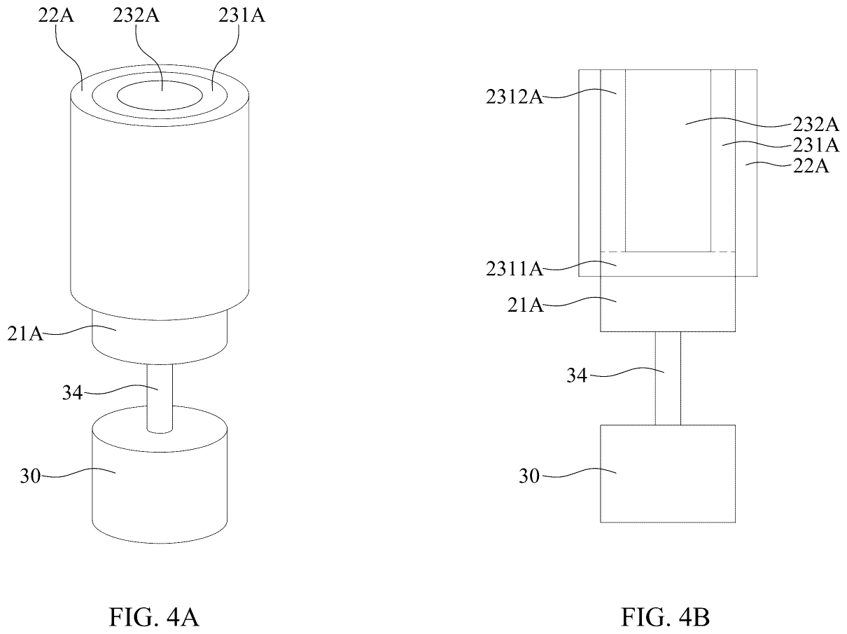

Embodiments of the channel region 23A can be provided. As shown in FIGS. 4A and 4B in some embodiments, the sidewalls 2312A of the channel layer 231A are linear and the central isolation structure 232A may have a rectangular cross section from the front view. The channel layer 231A is also linear corresponding to the sidewalls 2312A of the channel layer 231A. In some embodiments, the channel layer 231A is a single layer. In an alternative embodiments, the channel layer 231A may have two or more channel sublayers.

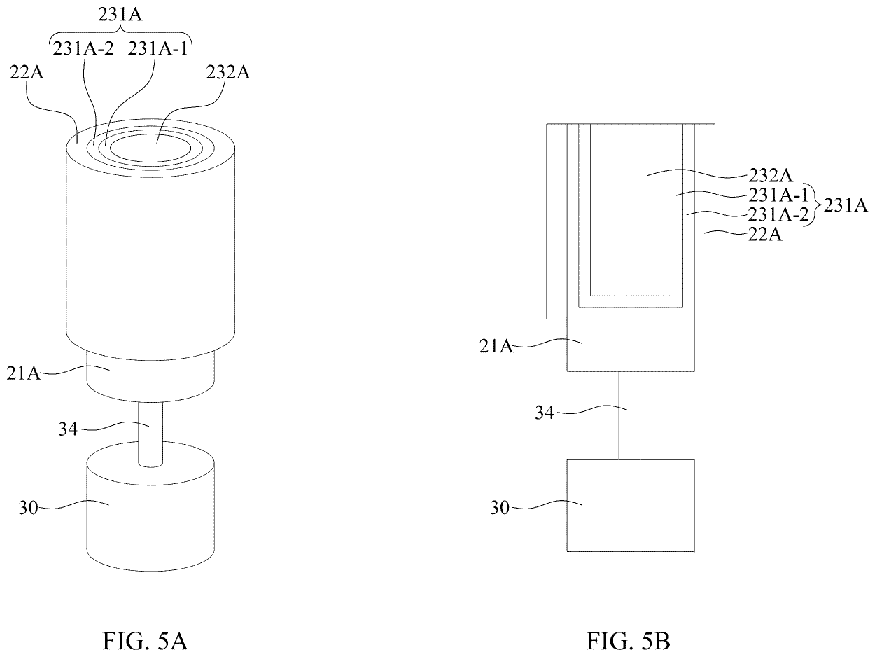

In some embodiments as shown in FIGS. 5A and 5B, the channel layer 231A comprises a first channel sublayer 231A-1 and a second channel sublayer 231A-2. The first channel sublayer 231A-1 surrounds a bottom and a sidewall of the central isolation structure 232A and may have a first doping concentration. The second channel sublayer 231A-2 surrounds the first channel sublayer 231A-1 and is formed between the first channel sublayer 231A-1 and the gate structures 22A and between the first channel sublayer 231A-1 and the first conductive region 21A. The second channel sublayer 231A-2 may have a second doping concentration, which may be greater or less than the first doping concentration. In some embodiments, the second doping concentration is greater than the first doping concentration, so the second channel sublayer 231A-2 may be highly doped or highly doped with p-type dopants or n-type dopants. The second channel sublayer 231A-2 can be a high doping channel and the first channel sublayer 231A-1 can be a low doping channel. These are, of course, merely examples and are not intended to be limiting.

The channel layer 231A may be an N-type channel or a P-type channel. When the channel layer 231A is an N-type channel, the channel layer 231A may comprise IGZO, ZnO, In₂O₃, SnO₂, and so on. When the channel layer 231A is a P-type channel, the channel layer 231A may comprise NiO, Cu₂°, CuAlO₂, CuGaO₂, CuInO₂, SrCu₂O₂, SnO, and so on. In some embodiments, the central isolation structure 232A may comprise material identical or similar to materials of the first dielectric layer 111, the second dielectric layer 113, the third dielectric layer 115, the fourth dielectric layer 121, or the fifth dielectric layer 123. In some embodiments, the central isolation structure 232A may comprise material identical to the fifth dielectric layer 123. In some embodiments, the central isolation structure 232A may comprise material identical to the sixth dielectric layer 125.

The gate structure 22A comprises a gate dielectric layer 221A and a gate electrode 222A. The gate dielectric layer 221A is disposed around the channel layer 231A and contacts the fifth insulating layer 124 so that the channel layer 231A is sandwiched by the gate dielectric layer 221A and the central isolation structure 232A. The gate dielectric layer 221A is partially disposed over the first conductive region 21A and partially disposed on the fourth insulating layer 122. The gate dielectric layer 221A may be formed of a high-k dielectric material, such as metal oxides, including but not limited to hafnium oxide (HfO2), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), SiO2, Al2O3, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂—Al₂O₃) alloy, other suitable high-k dielectric materials, or combinations thereof. Alternatively, the gate dielectric layer 221A may include silicon nitride, silicon oxynitride or silicon oxide. In some embodiments, the gate dielectric layer 221A may be formed using PVD, CVD or other suitable deposition methods. In some embodiments, the gate dielectric layer 221A may comprise HfO₂, SiO₂, Al₂O₃, SiON, and so on.

The gate electrode 222A is disposed along the gate dielectric layer 221A and between the fourth insulating layer 122 and the fifth insulating layer 124, so that each of the gate dielectric layers 221A is sandwiched by the gate electrode 222A and the channel layer 231A. The gate electrodes 222A connect the second conductive lines 32A through vias. The gate electrode 222A may include a metallic material, polycrystalline silicon, doped silicon, or a metal compound, such as metal nitride. The metallic material may include, for example, but not limited to, tungsten (W), silver (Ag), aluminum (Al), copper, nickel (Ni), other suitable materials, alloys thereof, or combinations thereof. The metal compound may include, for example, but not limited to, titanium nitride (TiN), tantalum nitride (TaN), metal silicide, other suitable materials, or combinations thereof. Other suitable materials for fabricating the gate electrode are within the contemplated scope of the present disclosure.

The sixth dielectric layer 125 is disposed over the fifth insulating layer 124 and on the plurality of channel regions 23A. In some embodiments, the sixth dielectric layer 125 may comprise materials identical or similar to materials of the fifth dielectric layer 123. A plurality of second conductive regions 24A are disposed in the sixth dielectric layer 125. Each of the plurality of second conductive regions 24A is disposed over the channel region 23A and electrically connects to the channel layer 231A. In some embodiments, the second conductive regions 24A may be referred to as source/drain regions. In some embodiments, the first conductive region 21A can be referred to as a source region, and the second conductive regions 24A can be referred to as drain regions. In some embodiments, the second conductive regions 24A comprise tungsten (W), copper (Cu), titanium nitride (TiN), tantalum nitride (TaN), aluminum (Al), ruthenium (Ru), cobalt (Co), indium tin oxide (ITO), doped semiconductor material (e.g., p-doped or n-doped silicon), and/or other metals. The second conductive regions 24A may comprise materials identical or similar to the materials of the first conductive regions 21A.

In some embodiments, within the logic area 10B, the second level 12B is formed over the first level 11B. In some embodiments, a plurality of dielectric layers (including a fourth dielectric layer 121, a fifth dielectric layer 123 and a sixth dielectric layer 125) and a plurality of insulating layers (including a fourth insulating layer 122 and a fifth insulating layer 124) stack alternately along a first direction D1. The layout of the second level 12B the logic area 10B is similar to the layout of the second level 12A the memory area 10A.

The fourth dielectric layer 121 in the logic area 10B is formed over the fifth insulating layer 124 in the first level 11B. The plurality of first conductive regions 21B are formed on the fifth insulating layer 124 and electrically connect to the plurality of conductive pads 40 by the plurality of second vias 42.

The fifth dielectric layer 123 is formed over the fourth insulating layer 122 and the first conductive region 21B. A plurality of channel regions 23B are formed in the fifth dielectric layer 123. Each of the plurality of channel regions 23B is surrounded by a gate structure 22B. Each of the plurality of channel regions 23B comprises a channel layer 231B and a central isolation structure 232B, which are identical in structure to the channel layer 231A and a central isolation structure 232A in the memory area 10A. The gate structure 22B comprises a gate dielectric layer 221B and a gate electrode 222B, which are identical in structure to the gate dielectric layer 221A and the gate electrode 222A in the memory area 10A.

The sixth dielectric layer 125 in the logic area 10B is disposed on the plurality of channel regions 23B. In some embodiments, a plurality of second conductive regions 24B are disposed in the sixth dielectric layer 125. Each of the plurality of second conductive regions 24B is disposed over the channel region 23B and electrically connects to the channel layer 231B.

Within the memory area 10A and the logic area 10B, the first conductive lines 60 are disposed in a seventh dielectric layer 61, which is disposed over the sixth dielectric layer 125 and. The first conductive lines 60 are arranged in parallel along a third direction D3, perpendicular to the first direction D1 and also perpendicular to the second direction D2. The first conductive lines 60 may be functioned as bit lines (BL). Each of the first conductive lines 60 electrically connects to the second conductive regions 24A in the memory area 10A and electrically connects to the second conductive regions 24B in the logic area 10B.

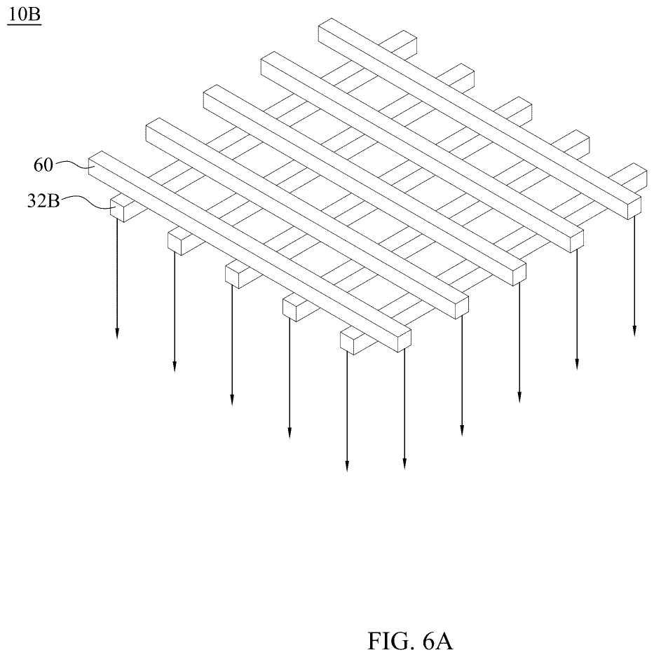

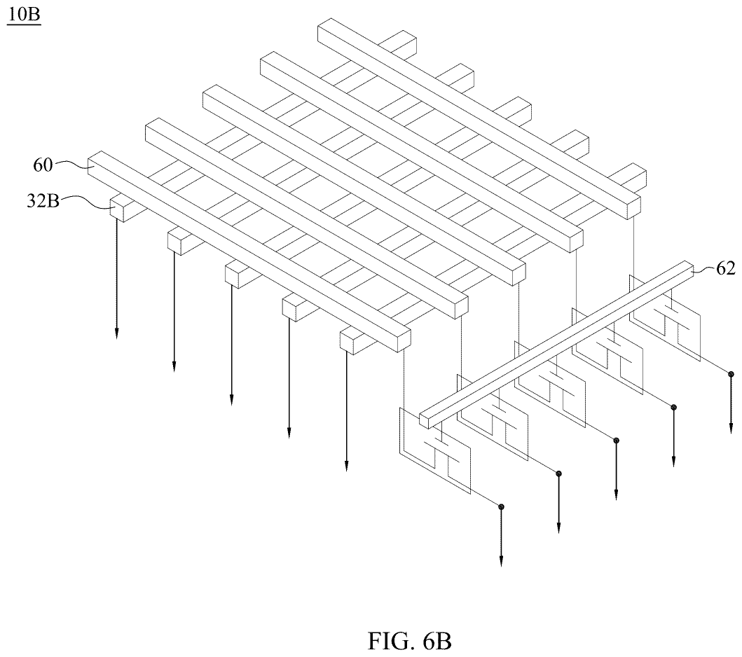

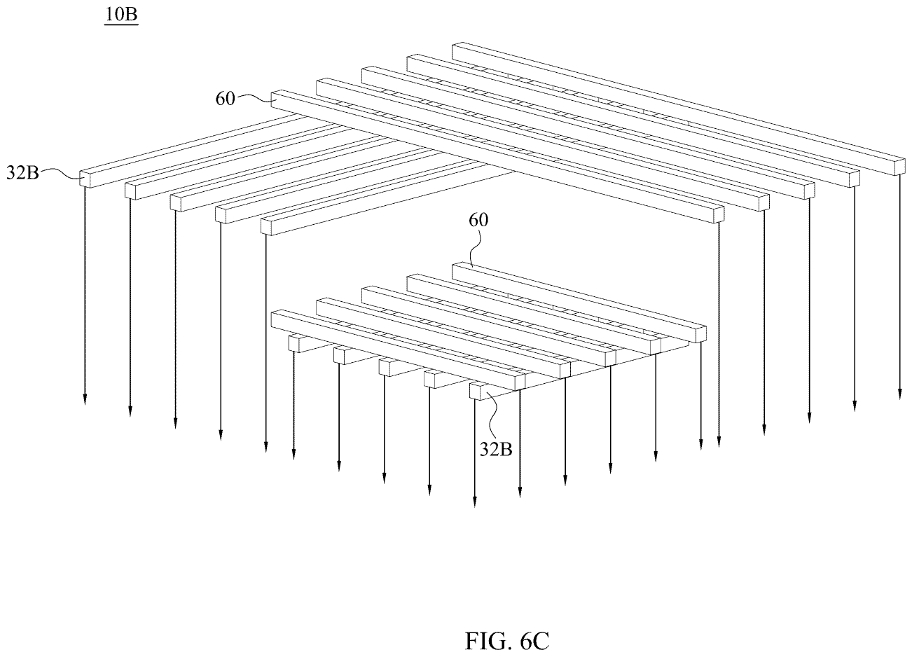

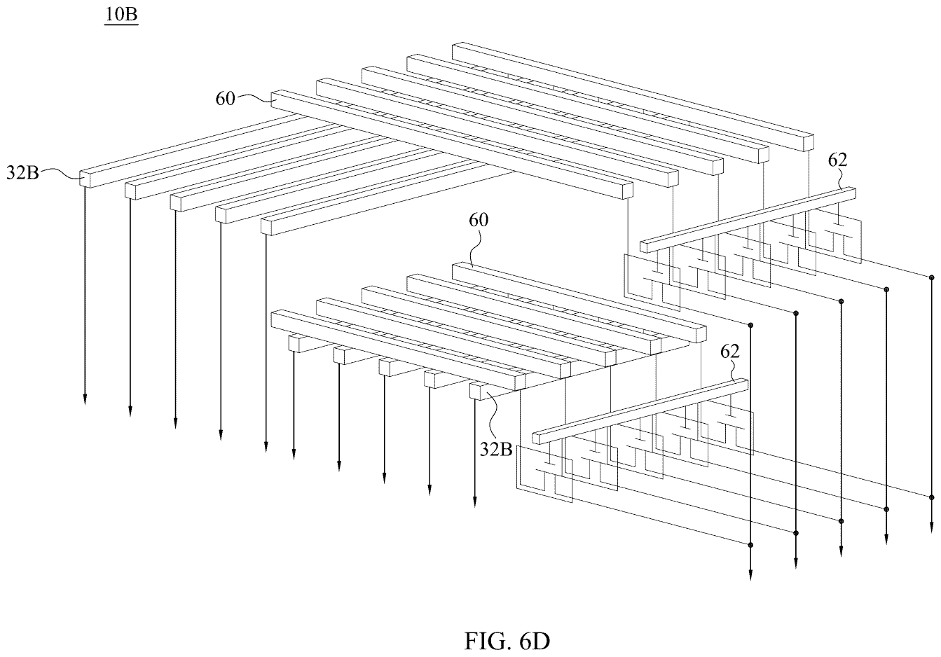

As shown in FIG. 6A to 6D, in the logic area 10B, a plurality of second conductive lines 32B are disposed in the first level 11B. In some embodiments, the plurality of second conductive lines 32B are electrically connected to the gate electrodes 222B through vias. The plurality of second conductive lines 32B in the logic area 10B may be functioned as word lines (WL) and electrically connect to elements disposed in the substrate 100. The plurality of first conductive lines 60 can electrically connect to the logic devices 50. In some embodiments, the first conductive lines 60 may electrically connect to the logic devices 50 through one or more switches 62 as shown in FIGS. 6B and 6D. In some embodiments as shown in FIGS. 6B and 6D, several sets of the first conductive lines 60 and the plurality of second conductive lines 32B can be used. Each set can be turned on/off in different circuit operation situations.

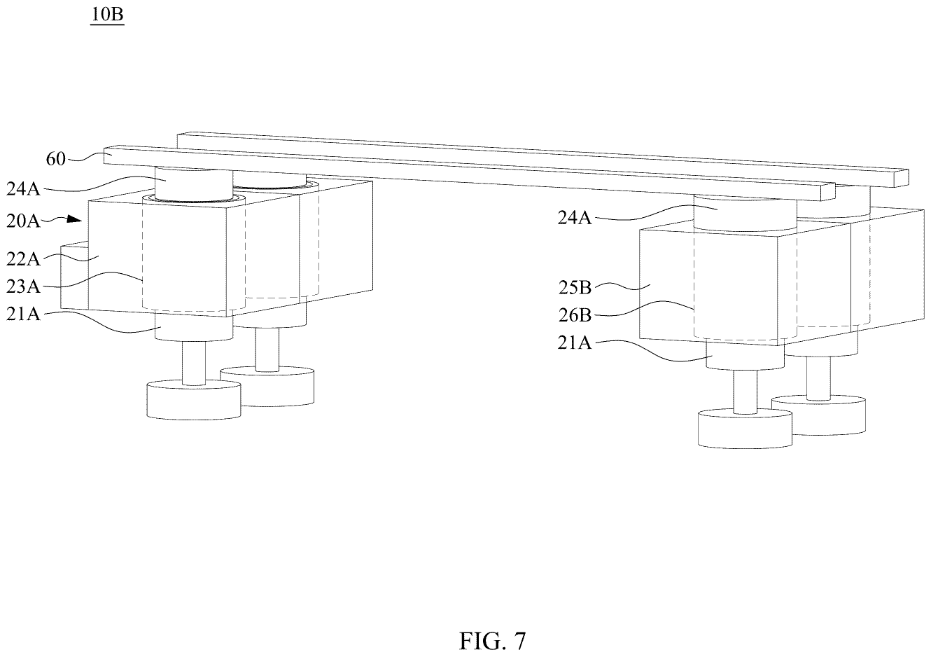

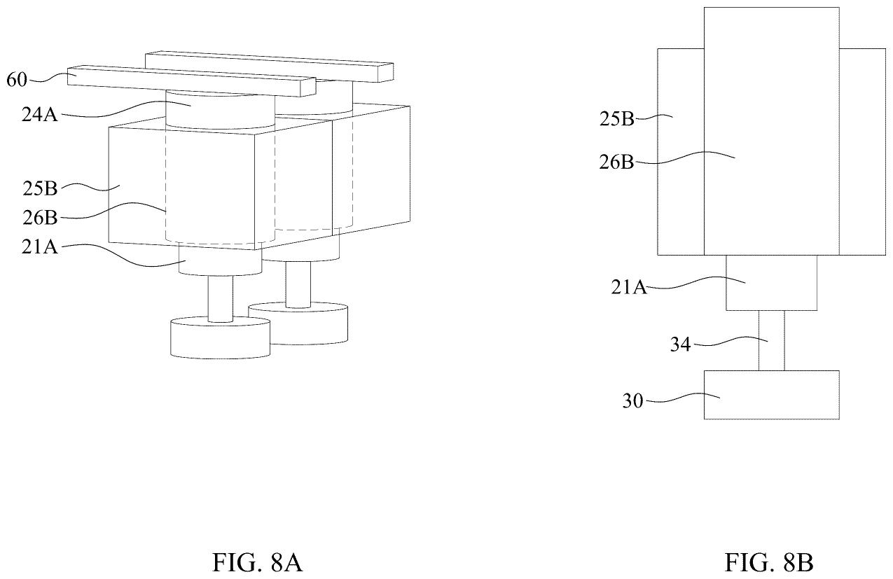

In some alternative embodiments, the structures of the gate structure 22B and the channel region 23B may be simplified. In some embodiments, dielectric materials may be filled in the location for forming the gate structure 22B so as to form an outer isolation structure 25B and conductive materials may be filled in the location for forming the channel region 23B so as to form a conductive structure 26B as shown in FIGS. 7, 8A and 8B. Such conductive structure 26B has better contact resistance, which can improve operation speed.

The configurations of the first conductive region 21A, the gate structure 22A, the channel region 23A and the second conductive region 24A in the memory area 10A may be varied; the configurations of the first conductive region 21B, the gate structure 22B, the channel region 23B and the second conductive region 24B in the logic area 10B may be correspondingly changed. For example, the transistor 20A and the counterpart transistor 20B may be planar transistors.

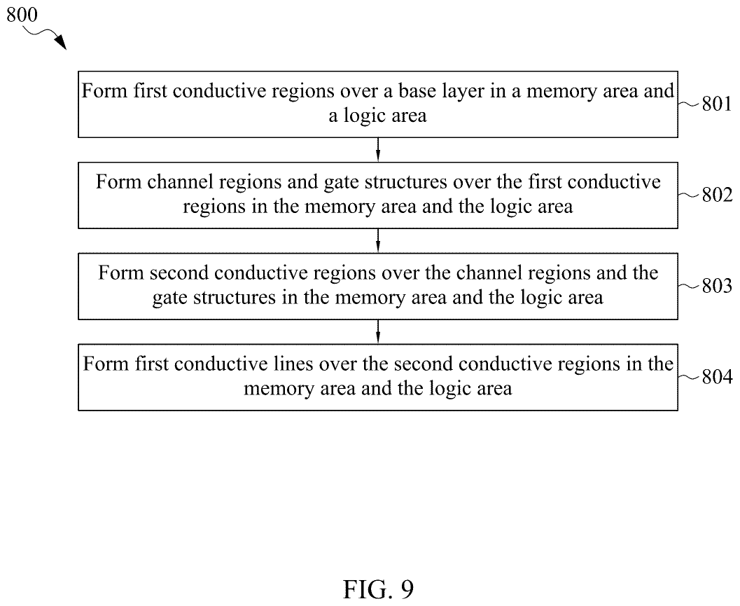

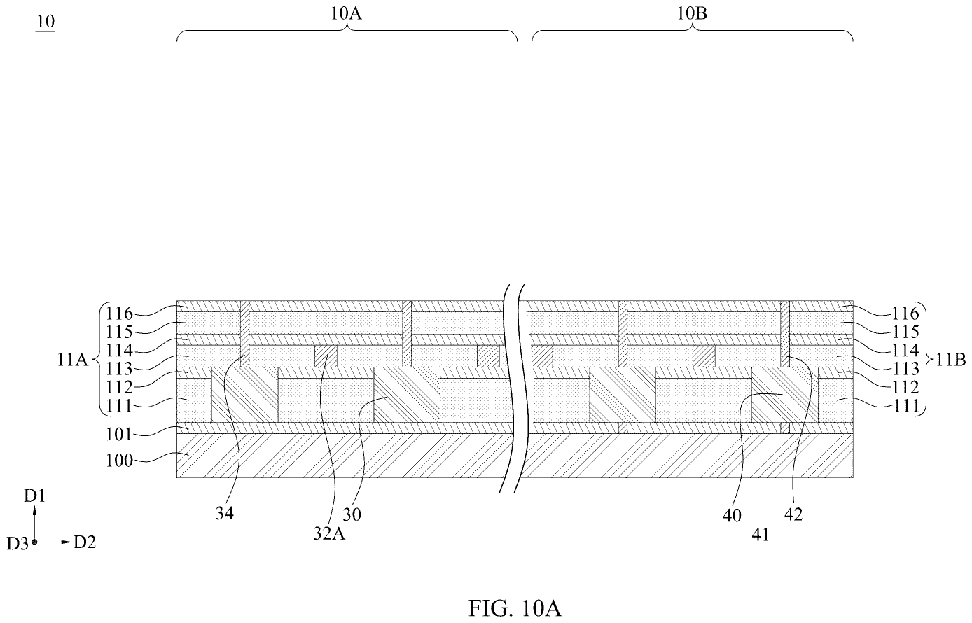

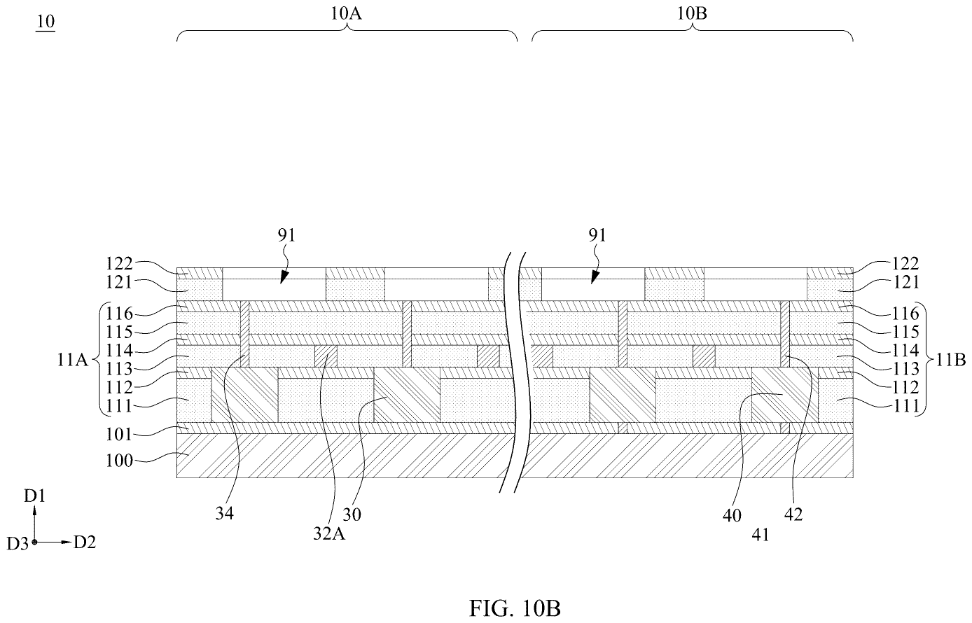

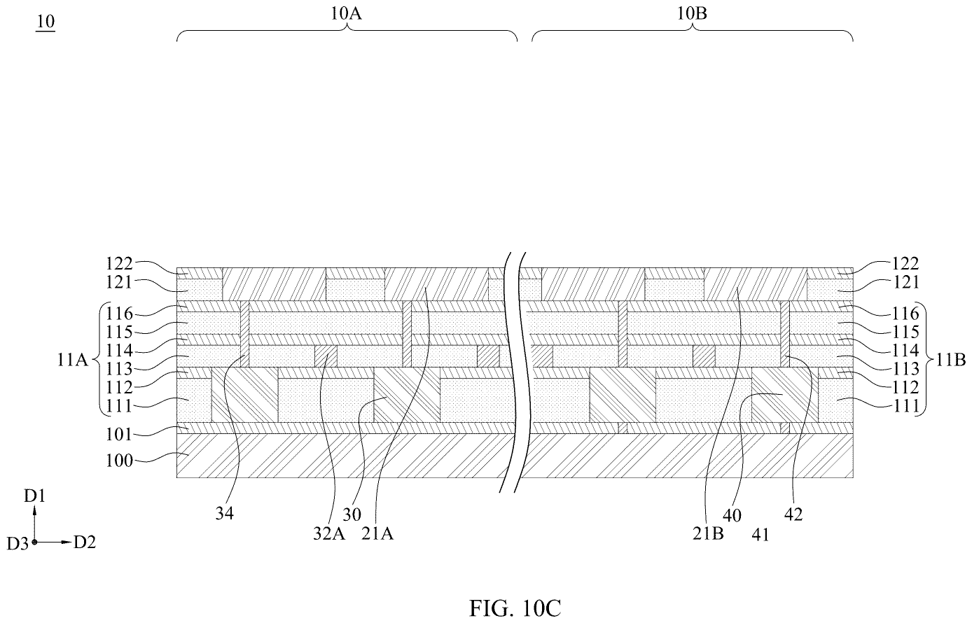

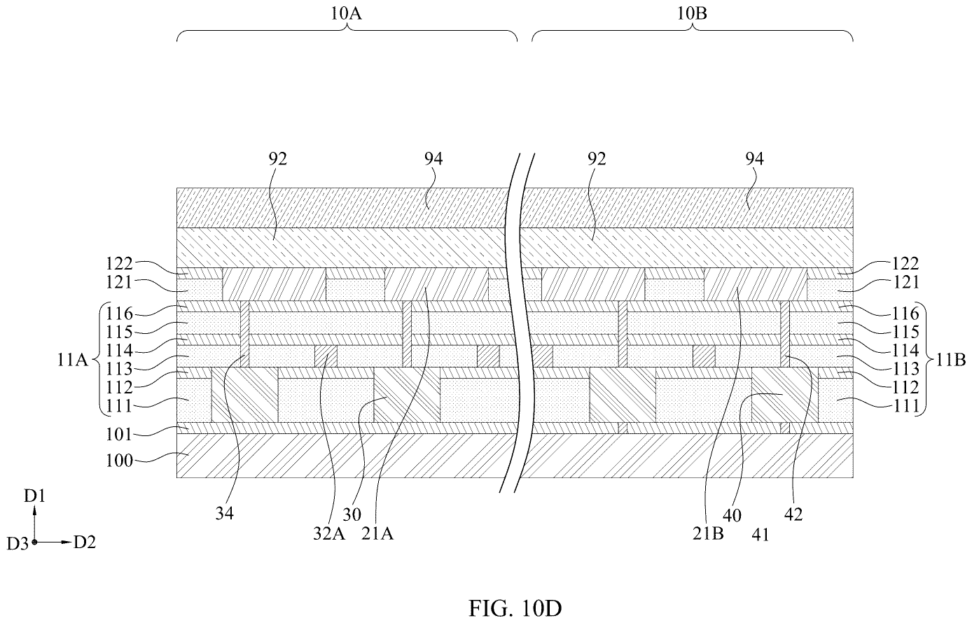

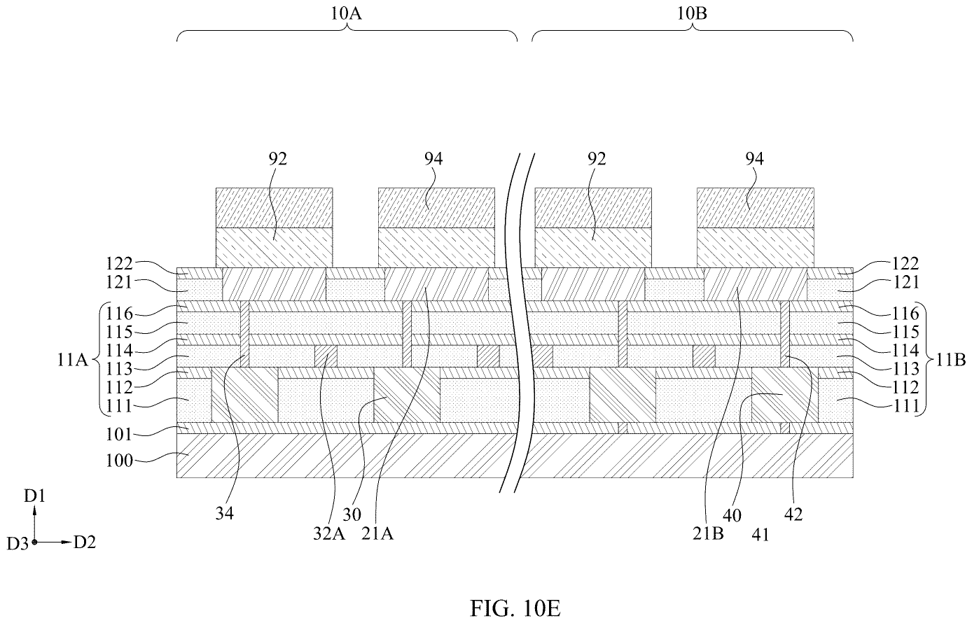

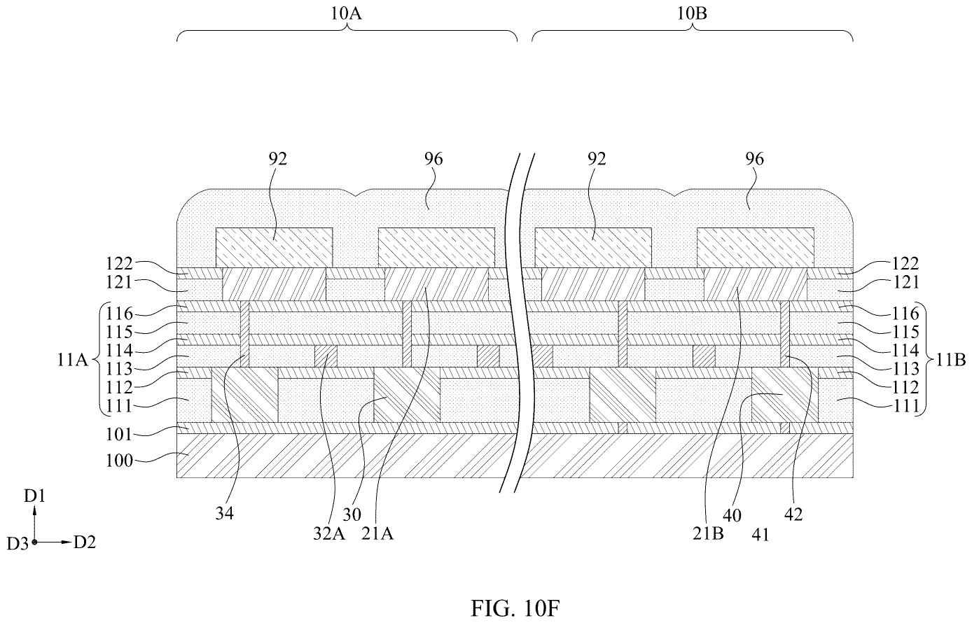

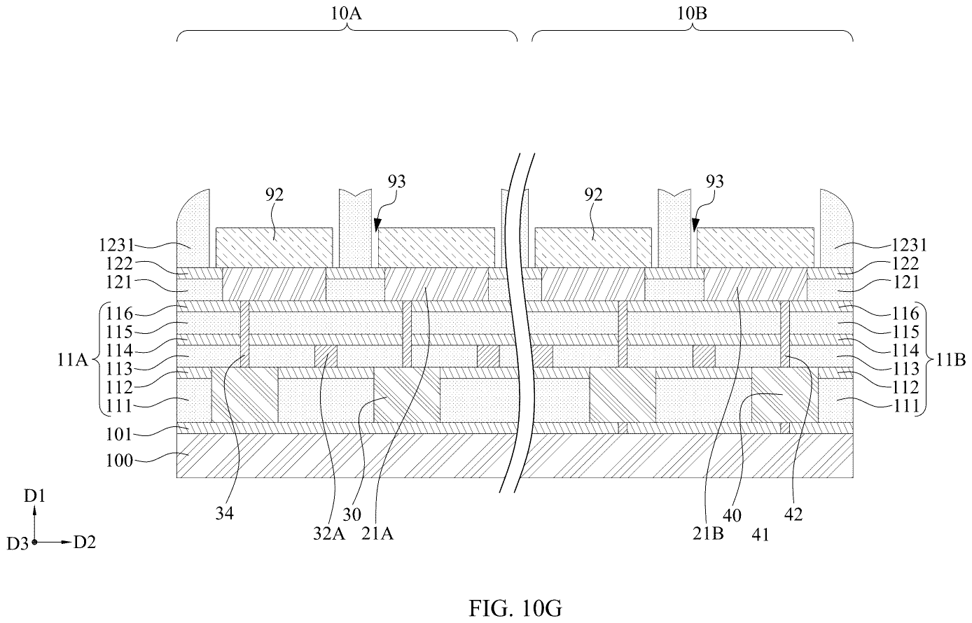

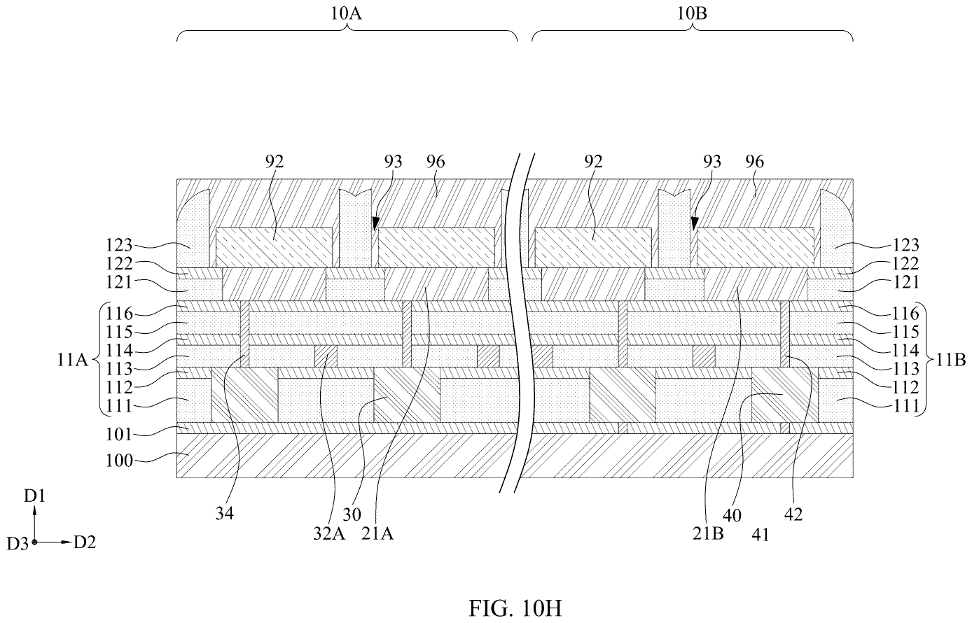

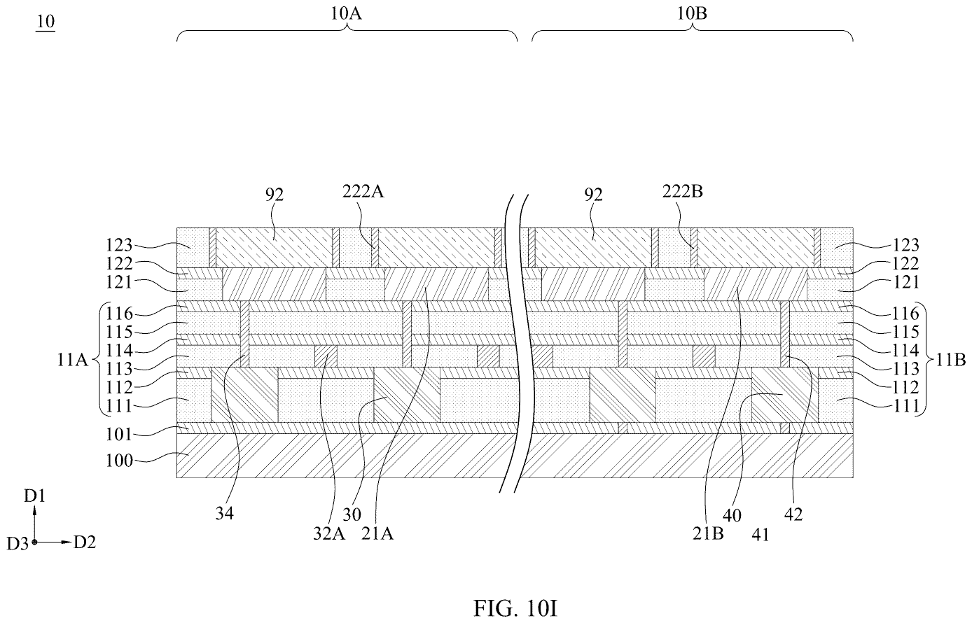

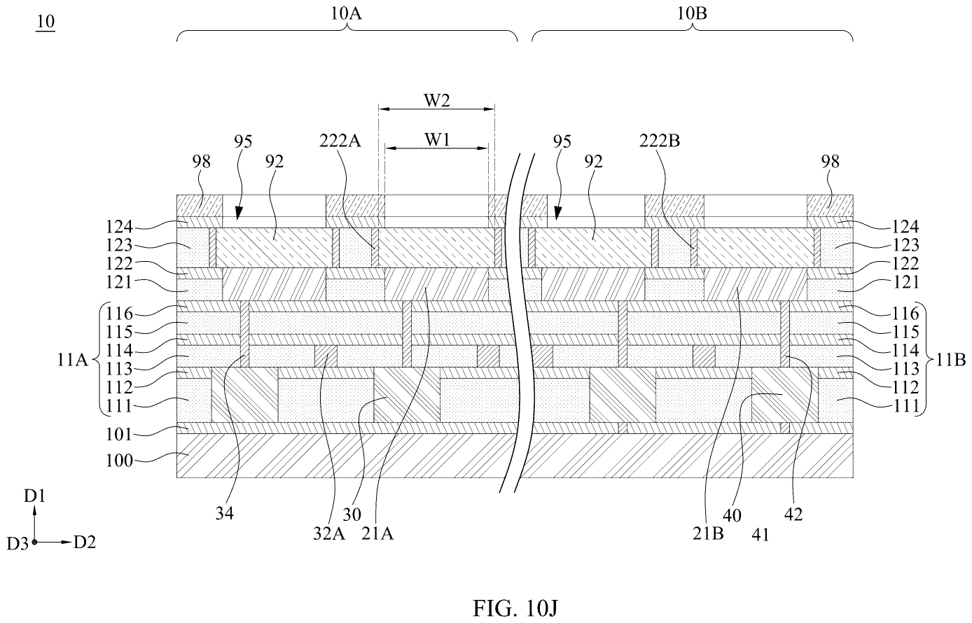

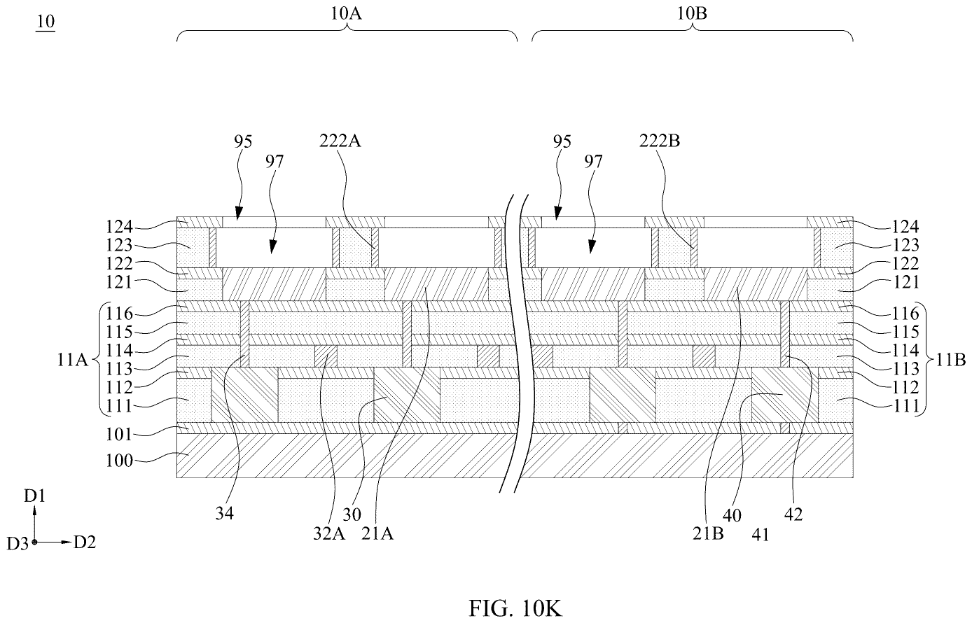

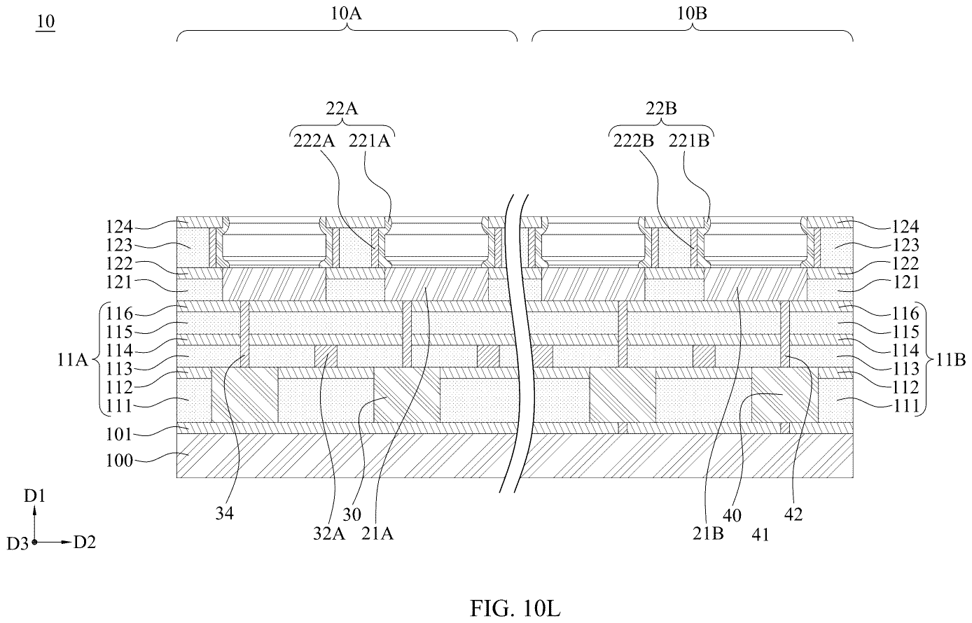

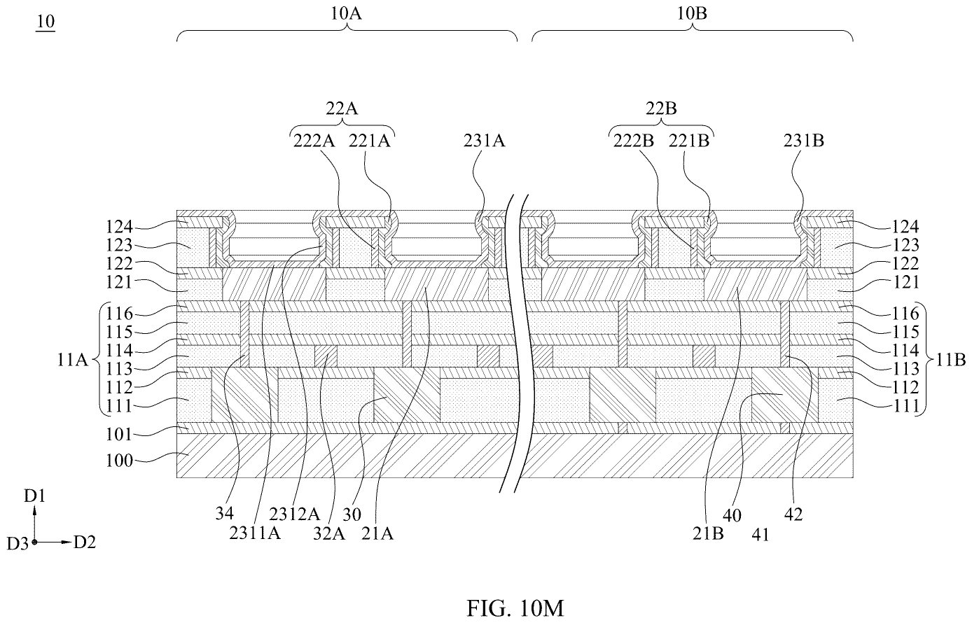

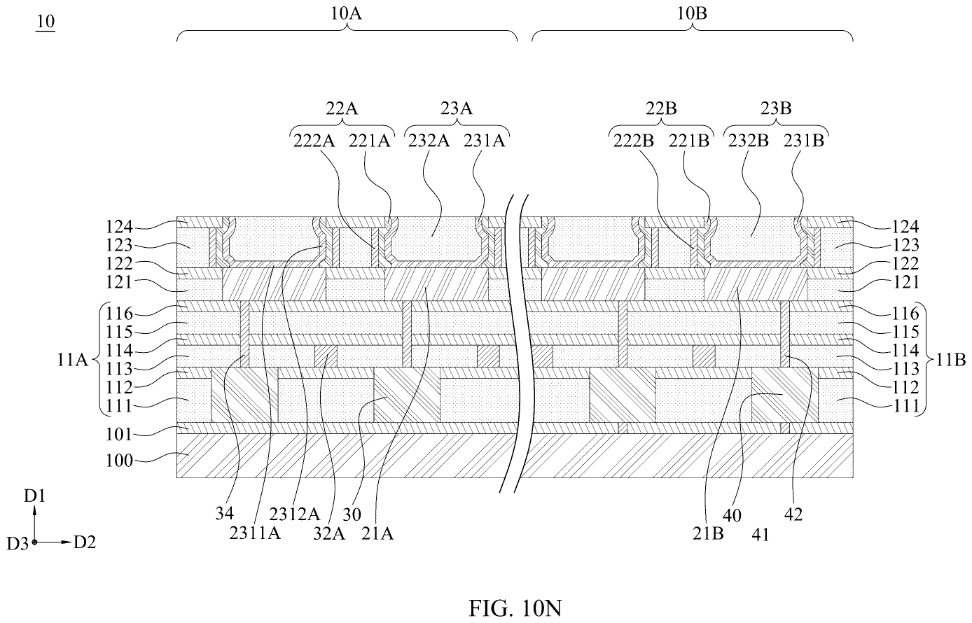

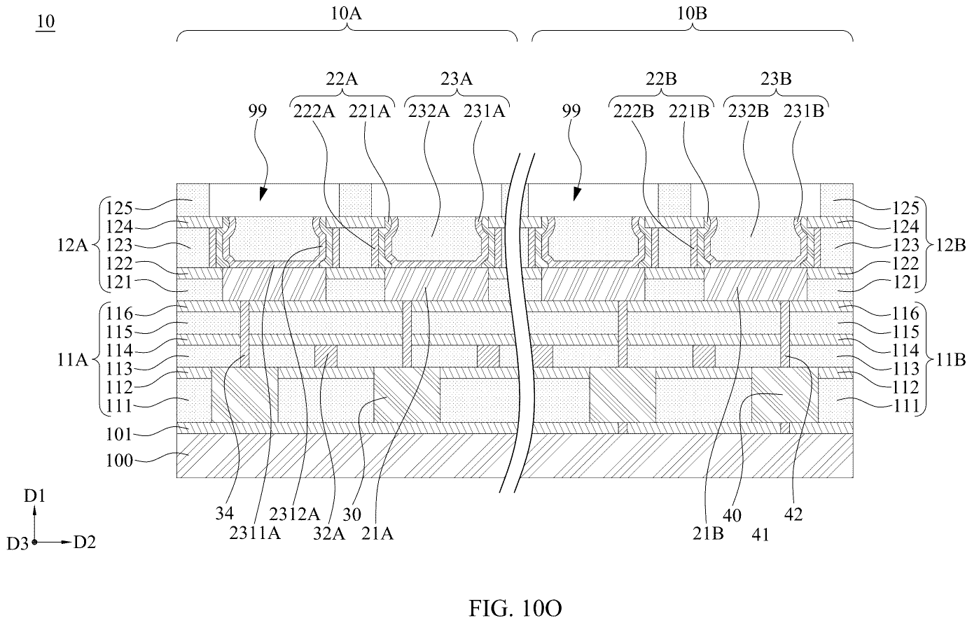

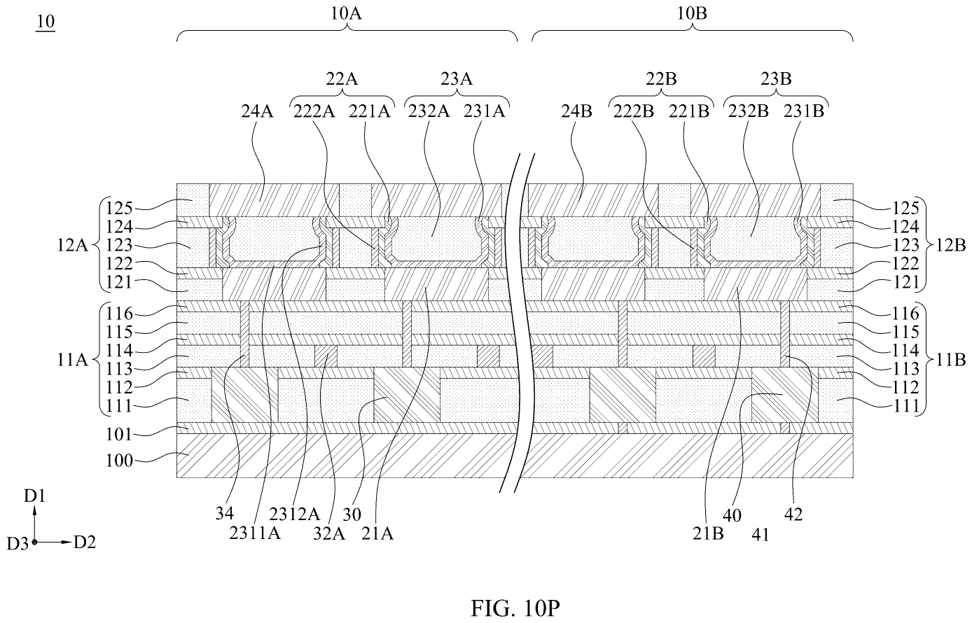

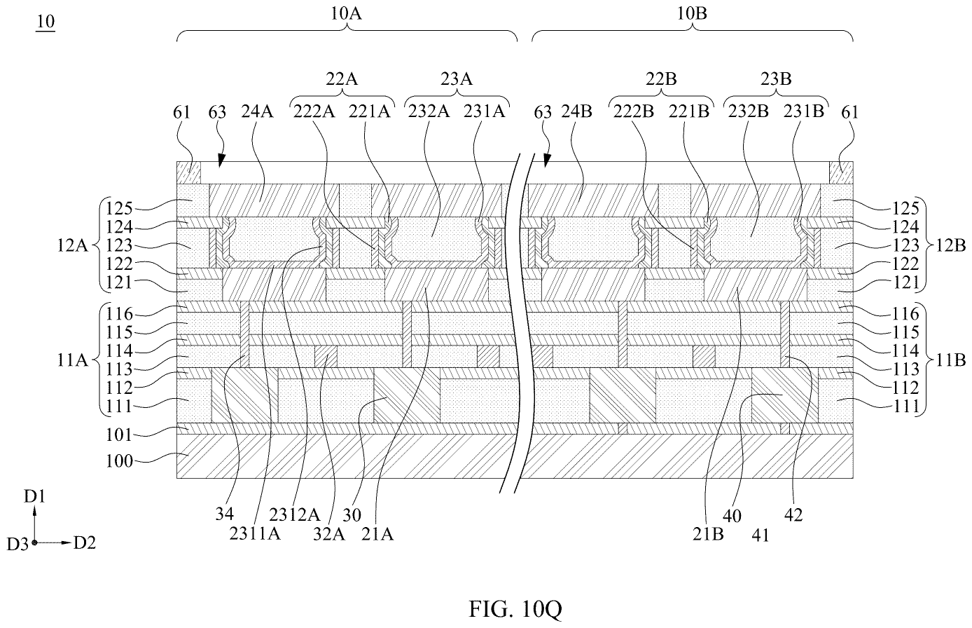

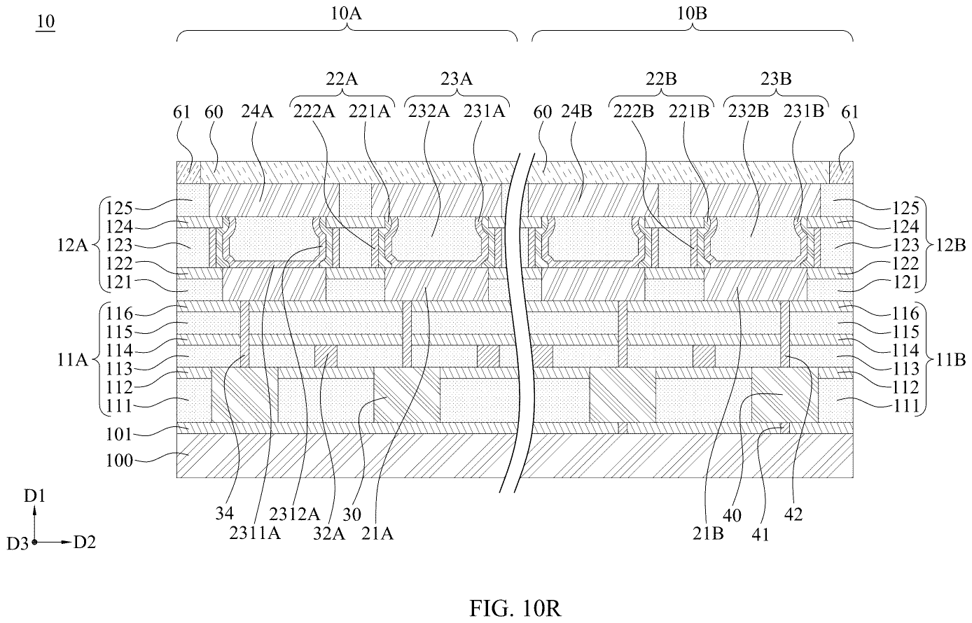

FIG. 9 is a flowchart representing a method 800 for forming a semiconductor structure according to various aspects of the present disclosure. In some embodiments, the method 800 for forming the semiconductor structure includes a number of operations (801, 02, 803 and 804). The method 800 for forming the semiconductor structure will be further described according to one or more embodiments. It should be noted that the operations of the method 800 may be rearranged or otherwise modified within the scope of the various aspects. It should further be noted that additional processes may be provided before, during, and after the method 800, and that some other processes may be only briefly described herein. FIGS. 10A to 10R are diagrammatic perspective views illustrating various stages in the method 800 for forming the semiconductor structure according to aspects of one or more embodiments of the present disclosure.

With reference to FIGS. 10A to 10C, the method 800 begins at operation 801 where first conductive regions are formed over a base layer in a memory area 10A and a logic area 10B. As shown in FIG. 10A, the base layer can be provided and received, which comprises a substrate 100 and a first level 11A and 11B in the memory area 10A and the logic area 10B synchronously. Within the memory area 10A, the first level 11A comprises a plurality of dielectric layers (including the first dielectric layer 111, the second dielectric layer 113 and the third dielectric layer 115) and a plurality of insulating layers (including the first insulating layer 112, the second insulating layer 114 and the third insulating layer 116) as mentioned above. Within the logic area 10B, the first level 11B comprises the plurality of conductive pads 40, and the plurality of second vias 42 are formed in first level 11B in the logic area 10B as mentioned above. Other layers and/or elements can be formed in the first level 11A in the memory area 10A and in the first level 11B in the logic area 10B. As shown in FIG. 10B, a fourth dielectric layer 121 and a fourth insulating layer 122 are formed over the base layer. The fourth insulating layer 122 and the fourth dielectric layer 121 are etched to form a plurality of first trenches 91. As shown in FIG. 10C, first conductive materials are applied to fill the first trenches 91 to form a plurality of first conductive region 21A in the memory area 10A and a plurality of first conductive region 21B in the logic area 10B. A planarization process (for example, but not limited to, chemical mechanical planarization (CMP)) may be performed so that a top of each of the plurality of first conductive region 21A and 21B is substantially coplanar with the fourth insulating layer 122. In some embodiments, the first conductive region 21A and 21B may be referred to as source/drain regions. In some embodiments, the first conductive region 21A and 21B can be referred to as source regions.

As shown in FIGS. 10D to 10N, the method 800 continues with operation 802 where a plurality of channel regions 23A and 23B and a plurality of gate structures 22A and 22B are formed over the first conductive regions in the memory area 10A and the logic area 10B synchronously. As shown in FIG. 10D, a first sacrificial layer 92 and a first hard mask 94 are formed over the fourth insulating layer 122 and the first conductive regions 21A and 21B in the memory area 10A and the logic area 10B synchronously. As shown in FIG. 10E, the first har mask 94 and the first sacrificial layer 92 are patterned to define locations for the plurality of channel regions 23A and 23B and the plurality of gate structures 22A and 22B and to partially expose the fourth insulating layer 122. As shown in FIG. 10F, the first hard mask 94 is removed; dielectric materials 1231 are formed over the patterned first sacrificial layer 92 and the exposed fourth insulating layer 122. As shown in FIG. 10G, the dielectric materials 1231 are patterned to remove portions of the dielectric materials 1231 surrounding the patterned first sacrificial layer 92 to form gaps 93, which are locations for gate electrodes 222A and 222B to be formed. As shown in FIG. 10H, conductive materials 96 are filled in the gaps 93 to form the gate electrodes 222A and 222B after being planarized as shown in FIG. 10I. Furthermore, the dielectric materials 1231 form a fifth dielectric layer 123 between every two of the gate electrodes 222A and 222B. As shown in FIG. 10J, a layer of insulating materials and a second hard mask 98 are formed over the fifth dielectric layer 123, the gate electrodes 222A and 222B and the patterned first sacrificial layer 92. The layer of insulating materials and the second hard mask are patterned through etching to form a fifth insulating layer 124 with a plurality of first recesses 95 to partially expose a top of each of the patterned first sacrificial layer 92. As shown in FIG. 10J, each of the first recesses 95 has a width W1, which is less than a width W2 of each of the patterned first sacrificial layer 92.

Further in view of FIG. 10K, the patterned first sacrificial layer 92 and the second hard mask 98 are removed to form second recesses 97. As shown in FIG. 10L, gate dielectric layers 221A and 221B are conformally formed along sidewalls of the second recesses 97 and sidewalls of the first recesses 95. As shown in FIG. 10M, channel layers 231A and 231B are formed on the first conductive region 21A and 21B and along the gate dielectric layers 221A and 221B and central isolation structures 232A and 232B are formed in the channel layers 231A and 231B. Materials for forming the channel layers 231A and 231B may be IGZO, ZnO, In₂O₃, SnO₂, and so on for an N-type channel, or NiO, Cu₂O, CuAlO₂, CuGaO₂, CuInO₂, SrCu₂O₂, SnO, and so on for a P-type channel. A planarization (for example, but not limited to, CMP) can be conducted, so that the channel layers 231A and 231B, the central isolation structures 232A and 232B, gate dielectric layers 221A and 221B and the fifth insulating layer 124 are substantially coplanar.

At operation 803 as illustrated in FIGS. 10O and 10P, a plurality of second conductive regions 24B over the channel regions 23A and 23B and the gate structures 22A and 22B in th memory area 10A and the logic area 10B synchronously. As shown in FIG. 10O, dielectric materials are formed over the fifth insulating layer 124, the gate dielectric layers 221A and 221B and the channel regions 23A and 23B, and are pattered through etching to form a sixth dielectric layer 125 with a plurality of second trenches 99 to expose tops of the channel regions 23A and 23B, tops of the gate dielectric layers 221A and 221B and a portion of the top of the fifth insulating layer 124. In some embodiments, a width of the second trench 99 may be greater than a width of the channel region 23A and 23B. As shown in FIG. 10P, conductive materials are applied to filled in the plurality of second trenches 99 to form second conductive regions 24A, which may be functioned as word lines (WL). A planarization (for example, but not limited to, CMP) can be conducted, so that tops of the second conductive regions 24A and 24B and a top of the sixth dielectric layer 125 are substantially coplanar.

At operation 804 as illustrated in FIGS. 10Q and 10R, first conductive lines 60 are formed over the second conductive regions 24A and 24B in the memory area 10A and the logic area 10B synchronously. As shown in FIG. 10Q, dielectric materials are formed over the sixth dielectric layer 125 and the second conductive regions 24A and 24B, and are patterned through etching to form the seventh dielectric layer 61 with grooves 63 defining the locations for forming the first conductive lines 60. Conductive materials are filled in the grooves 63 to form the plurality of first conductive lines 60 arranged in parallel along a third direction D3, perpendicular to the first direction D1 and also perpendicular to the second direction D2. The plurality of first conductive lines 60 may be functioned as bit lines (BL).

Since the second level 12A of the memory area 10A and the second level 12B of the logic area 10B have substantially identical layouts, both of the memory area 10A and the logic area 10B can be fabricated synchronously, which simplifies manufacturing process and saves costs. Furthermore, the logic area 10B may also comprise counterpart transistors 20B in replacement of deep bit-line vias, which can achieve high density and can function as on/off switches controlling elements in the logic area 10B.

In some embodiments, a method for manufacturing a semiconductor structure comprises providing a base layer comprising a memory element in a memory area and a logic device in a logic area, wherein the memory element and the logic device are disposed in different levels; forming a plurality of first conductive regions over the base layer in the memory area and the logic area, wherein the first conductive region in the memory area is electrically connected to the memory element, and the first conductive region in the logic area is electrically connected to the logic device through a conductive pad; forming a plurality of gate structures and a plurality of channel regions over the plurality of first conductive regions in the memory area and the logic area, wherein the channel regions are formed on and electrically connected to the plurality of first conductive regions and are surrounded by the plurality of gate structures; and forming a plurality of second conductive regions over the channel regions and the gate structures in the memory area and the logic area, wherein the second conductive regions are electrically connected to the channel regions, wherein the memory element in the memory area and the conductive pad in the logic area are formed in a same level.

In some embodiments, a method for manufacturing a semiconductor structure comprises providing a base layer comprising a capacitor in a memory area and a conductive pad in a logic area, wherein the conductive pad is electrically connected to a logic device in the logic area; forming a first transistor in the memory area and a second transistor in the logic area; and forming first conductive lines in the memory area and the logic area, wherein the first conductive lines extend from the memory area to the logic area and electrically connect to the capacitor in the memory area through the first transistor and, connect to the logic device in the logic area through the second transistor in the logic area wherein a top surface of the memory element in the memory area is substantially aligned with a top surface of the conductive pad in the logic area.

In some embodiments, a semiconductor structure comprises a base layer having a memory area including a memory element and a logic area including a logic device; first conductive regions disposed over the base layer in the memory area and the logic area, wherein the first conductive region in the memory area is electrically connected to the memory element, and the first conductive region in the logic area electrically connects to the logic device through a conductive pad; gate structures and channel regions disposed over the first conductive regions in the memory area and the logic area, wherein the channel regions are electrically connected to the first conductive regions and are surrounded by the gate structures; and second conductive regions disposed over the channel regions and the gate structures in the memory area and the logic area, wherein the second conductive regions are electrically connect to the channel regions, and wherein the memory element in the memory area and the conductive pad in the logic area are disposed in a same layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for manufacturing a semiconductor structure, comprising:
providing a base layer comprising a memory element in a memory area and a logic device in a logic area, wherein the memory element and the logic device are disposed in different levels;
forming a plurality of first conductive regions over the base layer in the memory area and the logic area, wherein the first conductive region in the memory area is electrically connected to the memory element, and the first conductive region in the logic area is electrically connected to the logic device through a conductive pad;
forming a plurality of gate structures and a plurality of channel regions over the plurality of first conductive regions in the memory area and the logic area, wherein the channel regions are formed on and electrically connected to the plurality of first conductive regions and are surrounded by the plurality of gate structures; and
forming a plurality of second conductive regions over the channel regions and the gate structures in the memory area and the logic area, wherein the second conductive regions are electrically connected to the channel regions,
wherein the memory element in the memory area and the conductive pad in the logic area are formed in a same level.

2. The method of claim 1, further comprising forming first conductive lines over the second conductive regions in the memory area and the logic area, wherein the first conductive lines extend from the memory area to the logic area.

3. The method of claim 1, wherein forming the gate structures and channel regions in the memory area and the logic area comprises:
forming a first sacrificial layer and a first hard mask over the first conductive regions;
patterning the first hard mask and the first sacrificial layer to form patterned first sacrificial regions so as to define locations for the channel regions and the gate structures;
removing the first hard mask;
forming dielectric materials over the patterned first sacrificial regions and into first gaps between the patterned first sacrificial regions;
patterning the dielectric materials to remove portions of the dielectric materials surrounding the patterned first sacrificial regions to form second gaps;
filling the second gaps with conductive materials to form gate electrodes and remaining dielectric materials form a dielectric layer between every two of the gate electrodes;
forming a layer of insulating materials and a second hard mask over the dielectric layer with the gate electrodes and the patterned first sacrificial regions;
patterning the layer of insulating materials and the second hard mask to form an insulating layer with a plurality of first recesses to partially expose a top of each of the patterned first sacrificial regions;
removing the patterned first sacrificial regions and the second hard mask to form second recesses;
conformally forming a dielectric layer along sidewalls of the second recesses and sidewalls of the first recesses to form gate dielectric layers;
forming channel layers on the first conductive regions and along the gate dielectric layers; and
forming central isolation structures in the channel layers.

4. The method of claim 3, wherein each of the first recesses has a width, which is less than a width of each of the patterned first sacrificial regions.

5. The method of claim 3, wherein each of the channel layers comprises a first channel sublayer and a second channel sublayer, and wherein the first channel sublayer has a dopant concentration, which is different from a dopant concentration of the second channel sublayer.

6. The method of claim 2, wherein the base layer in the memory area further comprises second conductive lines over the memory element, and the second conductive lines electrically connect to the gate structures in the memory area.

7. The method of claim 2, wherein the base layer in the logic area further comprises second conductive lines electrically connect to the gate structures in the logic area.

8. The method of claim 2, wherein one of the first conductive regions and the second conductive regions serve as source regions, and an other of the first conductive regions and the second conductive regions serve as drain regions.

9. A method for manufacturing a semiconductor structure, comprising:
providing a base layer comprising a capacitor in a memory area and a conductive pad in a logic area, wherein the conductive pad is electrically connected to a logic device in the logic area;
forming a first transistor in the memory area and a second transistor in the logic area; and
forming first conductive lines in the memory area and the logic area, wherein the first conductive lines extend from the memory area to the logic area and electrically connect to the capacitor in the memory area through the first transistor and, connect to the logic device in the logic area through the second transistor in the logic area, wherein a top surface of the capacitor in the memory area is substantially aligned with a top surface of the conductive pad in the logic area.

10. The method of claim 9, wherein the base layer in the memory area further comprises second conductive lines electrically connected to the first transistor in the memory area.

11. The method of claim 10, wherein the first conductive lines are arranged in parallel along a first direction, and the second conductive lines are arranged in parallel along a second direction perpendicular to the first direction.

12. The method of claim 9, wherein the base layer in the memory area further comprises second conductive lines electrically connecting to second transistor in the logic area.

13. The method of claim 9, wherein each of the first transistor and second transistor comprises a channel region, and the channel region comprises a first channel sublayer and a second channel sublayer, and wherein the first channel sublayer has a dopant concentration, which is different from a dopant concentration of the second channel sublayer.

14. A semiconductor structure, comprising:
a base layer having a memory area including a memory element and a logic area including a logic device;
first conductive regions disposed over the base layer in the memory area and the logic area, wherein the first conductive region in the memory area is electrically connected to the memory element, and the first conductive region in the logic area electrically connects to the logic device through a conductive pad;
gate structures and channel regions disposed over the first conductive regions in the memory area and the logic area, wherein the channel regions are electrically connected to the first conductive regions and are surrounded by the gate structures; and
second conductive regions disposed over the channel regions and the gate structures in the memory area and the logic area, wherein the second conductive regions are electrically connect to the channel regions, wherein the memory element in the memory area and the conductive pad in the logic area are disposed in a same layer.

15. The semiconductor structure of claim 14, wherein
each of the channel regions comprises a central isolation structure and a channel layer serving as a bottom and a sidewall of the central isolation structure, and the channel layer electrically connects to the first conductive region; and
each of the gate structures comprises:
a gate dielectric layer formed around the channel layer so that the channel layer is sandwiched by the gate dielectric layer and the central isolation structure; and
a gate electrode formed along the gate dielectric layer.

16. The semiconductor structure of claim 15, wherein the channel layer comprises a first channel sublayer and a second channel sublayer, and wherein the first channel sublayer has a dopant concentration, which is different from a dopant concentration of the second channel sublayer.

17. The semiconductor structure of claim 15, wherein the central isolation structure has an oblate cross-section with narrower top and narrower bottom than a middle portion.

18. The semiconductor structure of claim 14, wherein the memory element and the conductive pad are disposed over the logic device.

19. The semiconductor structure of claim 14, further comprising first conductive lines over the second conductive regions in the memory area and the logic area, wherein the first conductive lines extend from the memory area to the logic area and electrically connect to the second conductive regions in the memory area and the logic area.

20. The semiconductor structure of claim 19, wherein the base layer in the memory area further comprises second conductive lines electrically connecting to the gate structures in the memory area.
